(19) United States
(12) Patent Application Publication
(10) Pub. No.: US 2014/0375319 A1
(43) Pub. Date: Dec. 25, 2014

(54) Transmitting Unit for a Magnetic Resonance Imaging System

(71) Applicant: Volker Matschl, Bamberg (DE)

(72) Inventor: Volker Matschl, Bamberg (DE)

(21) Appl. No.: 14/311,230

(22) Filed: Jun. 20, 2014

(30) Foreign Application Priority Data
Jun. 21, 2013 (DE) 102013211842.2
Jul. 9, 2013 (DE) 102013213400.2

(51) Int. Cl. G01R 33/38; G01R 33/00

(52) U.S. Cl. CPC G01R 33/38; G01R 33/0052
USPC 324/322; 29/592.1

(57) ABSTRACT

A transmitting unit for a magnetic resonance imaging system includes a signal generating unit, an amplifier connected downstream of the signal generating unit, a power splitter connected downstream of the amplifier, and a plurality of electrically decoupled transmitting coils connected downstream of the power splitter. A connectable phase shifter is arranged between the power splitter and at least one transmitting coil of the plurality of electrically decoupled transmitting coils.

This application claims the benefit of DE 10 2013 211 842.2, filed on Jun. 21, 2013, and DE 10 2013 213 400.2, filed on Jul. 9, 2013, which are hereby incorporated by reference in their entirety.

### BACKGROUND

The present embodiments relate to a transmitting unit for a magnetic resonance imaging system.

Magnetic resonance imaging (MRI) may be used to generate slice images of the human or animal body that allow an assessment of the organs and many pathological organ changes. MRI is based on very strong magnetic fields and alternating magnetic fields in the radio-frequency range (e.g., generated in an MRI) that resonantly excite specific atomic nuclei (e.g., the hydrogen nuclei/protons) in the body, as a result of which an electrical signal is induced in a receiver circuit.

MRI systems may have a transmitting unit that is provided for generating a substantially homogeneous radio-frequency field for exciting the nuclear spins. In this case, the associated transmitting coil may be configured as a “body coil” and may be fixedly incorporated in magnets and gradient coils. For the spatial resolution of the signals, a frequency and phase coding is mapped in the pulse sequences transmitted via the transmitting coil. In a corresponding signal generating unit connected upstream of the transmitting coil, therefore, a corresponding module for generating frequency and phase variations is provided. The module drives a digitally controlled oscillator and generates the corresponding oscillations. The generated modulated signal is communicated to an amplifier (e.g., radio-frequency power amplifier (RFPA)). The RFPA amplifies the signal and outputs the amplified signal to the transmitting coil.

1.5 tesla or 3 tesla MRI systems may be used in a clinical environment. A higher magnetic field strength of 7 teslas, for example, is striven for, however, since the recorded MRI signal is significantly higher. In the case of such higher field strengths (>3 T), instead of the body coil, a plurality of local coils are used for transmission in order to generate an excitation field that is as homogeneous as possible. These are antenna systems fitted in direct proximity on, below or in the body. Disturbing inhomogeneities caused by dielectric resonances are reduced in comparison with excitation by a whole body resonator.

However, many MRI systems have only one individual RFPA. In order to be able to operate multi-channel local coils, power splitters that split the power of the RFPA among the individual transmission channels are connected downstream. However, such a system is comparatively inflexible since a further setting or fine adjustment of the transmission signal on the individual channels is not possible.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a transmitting unit for a magnetic resonance imaging system that allows a high flexibility in the use of a plurality of local coils with an individual amplifier is provided.

A connectable phase shifter is arranged between the power splitter and at least one of the transmitting coils to allow the high flexibility.

One or more of the present embodiments are based on the consideration that the comparatively low flexibility of local coils connected by a power splitter is caused by the fact that in a power splitter, a fixed phase and the same amplitude is assigned to each channel. This may be remedied with a genuine multi-channel system with an RFPA and a signal generating unit for each individual channel. However, this produces a comparatively high outlay with respect to hardware. Existing single-channel systems may not be retrofitted. In order to achieve an individual adjustment of the channels emerging from a power splitter despite an individual RFPA, a phase shifter is assigned to the channels (e.g., to all channels apart from one). The phase shifter may be configured such that the phase shifter may be connected individually. An optimization of the homogeneity of the magnetic field is made possible as a result.

In one configuration, the respective phase shifter is configured as a discrete phase shifter (e.g., serves for shifting the phase by a previously defined frequency value). This is possible, for example, with a connectable delay line. A plurality of discrete phase shifters may be connected in series in order to enable phase shifts of a plurality of different values (e.g., discrete values).

In a further advantageous configuration, the respective phase shifter is configured as a variable-capacitance diode. The variable-capacitance diode or varicap (e.g., varactor or tuning diode) is an electronic semiconductor component in which a variation of the capacitance of 10:1 may be achieved by the applied voltage being changed. An electrically controllable capacitance that may be used as a continuously variable phase shifter is thus available.

A connectable damping element is advantageously arranged between the power splitter and at least one of the transmitting coils. As a result, besides the variation of the phase, the amplitude of the signal may be varied for the individual local coils.

In one advantageous configuration, the respective phase shifter and/or the respective damping element are/is connectable by a PIN diode. PIN diodes may be used as radio-frequency switches and are able to switch the loads that occur comparatively rapidly. This may be effected in an automated manner or by corresponding manual setting possibilities in a user interface.

In a further advantageous configuration, the transmitting unit is configured to drive the respective phase shifter and/or the respective damping element based on operating parameters of the respectively connected transmitting coil. The operating parameters for the transmitting and receiving mode of the coil may be stored in the coil file in the coil and may be read out by the central control unit of the MRI system. Depending on these operating parameters, the phases and amplitudes of the transmission signals may be set in relation to the respective local coils, such that an optimization of the homogeneity of the magnetic field is achieved.

In one alternative or additional advantageous configuration, the transmitting unit is configured to drive the respective phase shifter and/or the respective damping element based on a test measurement of the magnetic field of the magnetic resonance imaging system. In this case, the body to be examined is introduced into the MRI system before the actual measurement, and the inhomogeneities are determined. The optimum connection of the phase shifters and/or damping elements for a homogenization is determined based on the inhomogeneities determined.

Advantageously, the transmitting unit also has a Butler matrix. Using the Butler matrix, additional modes may be excited and connected in order to achieve the homogenization of the magnetic field. Such a configuration also enables an embodiment as an independent device in the manner of an adapter between installation and coil for extending the MRI system to, for example, eight virtual channels. The PIN diodes may be connected via the control line of the installation.

A method for retrofitting a magnetic resonance imaging system upgrades the magnetic resonance imaging system advantageously for using a number of electrically decoupled transmitting coils that is greater than the number of amplifiers present by virtue of the transmitting unit being configured as described.

A magnetic resonance imaging system advantageously includes a transmitting unit described.

The advantages achieved by one or more of the present embodiments includes, for example, that the introduction of connectable phase shifters and/or damping elements into the output channels of a power splitter in an MRI system makes an individual setting of the channels in relation to the individual transmitting coils possible with regard to phase and amplitude, even though the system includes fewer amplifiers than transmitting coils. As a result, an optimization of the homogenization of the magnetic field is achieved, which improves the measurement results.

### BRIEF DESCRIPTION OF THE DRAWINGS

FIG. 1 shows one embodiment of a transmitting unit of a magnetic resonance imaging system with a power splitter;

FIG. 2 shows one embodiment of a transmitting unit of a magnetic resonance imaging system with a Butler matrix; and

FIG. 3 shows one embodiment of a magnetic resonance imaging system with parts for transmission and reception.

### DETAILED DESCRIPTION

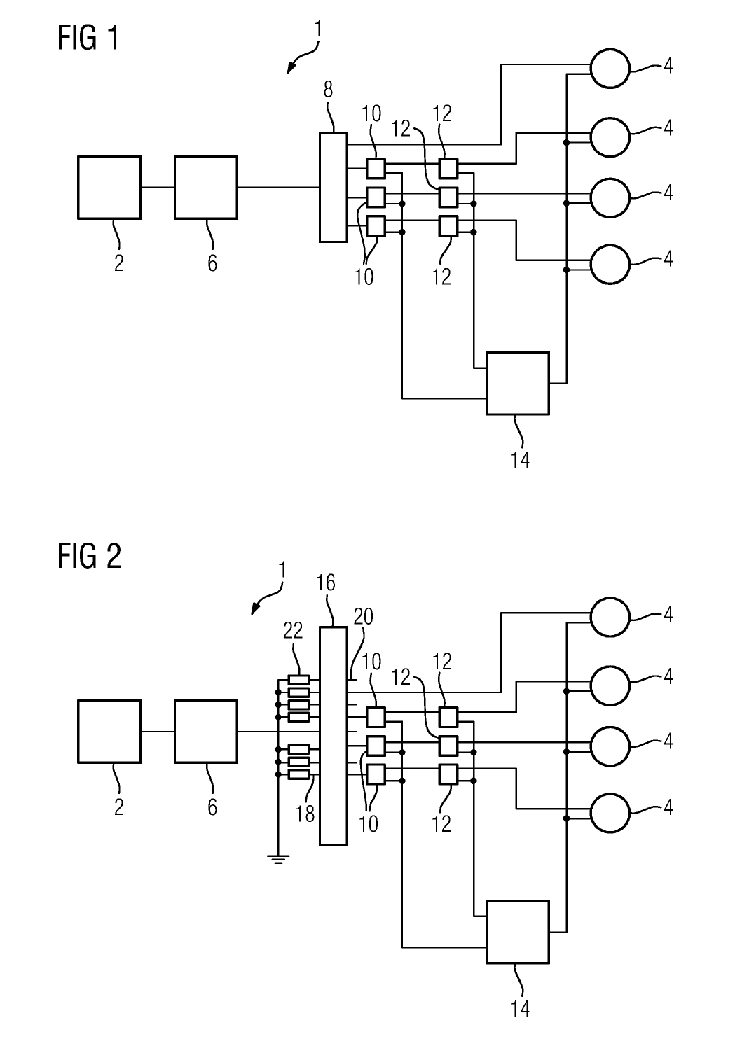

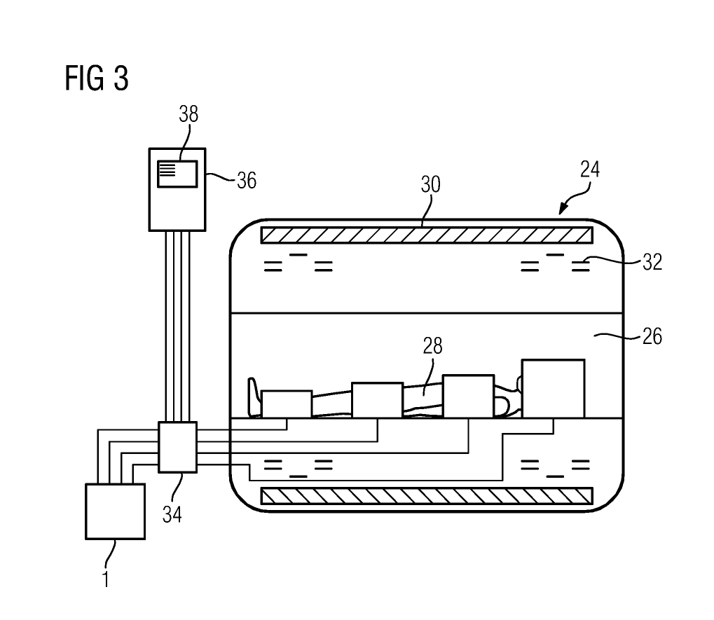

FIG. 1 schematically shows one embodiment of a transmitting unit 1 in a magnetic resonance imaging system 24, which is also described below in FIG. 3. A signal generating unit 2 and four electrically decoupled transmitting coils 4 designed as local coils are shown.

Further parts of the magnetic resonance imaging system 24 are shown schematically in section in FIG. 3. A patient 28 arranged in a cylindrical tunnel 26 is enclosed by a strong magnet 30, which generates a magnetic field of, for example, 7 teslas. Gradient coils 32, which likewise enclose the patient 28 in different axial regions and may superimpose gradient fields, are also provided. The gradient coils 32 are also driven by the transmitting unit 1, this not being graphically illustrated for the sake of clarity. The four transmitting coils 4 are arranged at the patient. The principle of the MRI measurement is explained briefly below.

The actual measurement takes place according to the principle of the spin echo sequence. In this context, a “sequence” (e.g., “pulse sequence”) is a combination of radio-frequency pulses emitted by the transmitting coils 4 and magnetic gradient fields generated in the gradient coils 32 and having a specific frequency or strength, which are switched on and off many times in every second in a predefined order. At the beginning, there is a radio-frequency pulse having the appropriate frequency (e.g., Larmor frequency), the 90° excitation pulse. The 90° excitation pulse deflects the magnetization by 90° transversely with respect to the external magnetic field. The magnetization starts to revolve around the original axis (e.g., precession).

The radio-frequency signal that arises in this case may be measured outside the body. The radio-frequency signal decreases exponentially because the proton spins move out of “step” (e.g., “dephase”) and are increasingly superimposed destructively. The time after which 63% of the signal has decayed is the relaxation time (e.g., spin-spin relaxation). This time is dependent on the chemical environment of the hydrogen. The time differs for every type of tissue. Tumor tissue may have, for example, a longer time than normal muscle tissue. A weighted measurement therefore represents the tumor in a manner brighter than surroundings of the tumor.

In order to be able to assign the measured signals to the individual volume elements (e.g., voxels), a spatial coding is generated with the linearly location-dependent magnetic fields (e.g., gradient fields). This makes use of the fact that for a specific particle, the Larmor frequency is dependent on the magnetic flux density (e.g., the stronger the field component perpendicular to the direction of the particle angular momentum, the higher the Larmor frequency). A gradient is present during the excitation and provides that only an individual slice of the body has the appropriate Larmor frequency (e.g., only the spins of this slice are deflected (slice selection gradient)). A second gradient transversely with respect to the first is briefly switched on after the excitation and brings about a controlled dephasing of the spins such that in each image line the precession of the spins has a different phase angle (e.g., phase coding gradient). The third gradient is switched during the measurement at right angles with respect to the other two gradients. The third gradient provides that the spins of each image column have a different precession velocity (e.g., transmit a different Larmor frequency (read-out gradient, frequency coding gradient)). All three gradients together thus bring about a coding of the signal in three spatial planes.

In the magnetic resonance imaging system 24 in FIG. 3, the signal is received likewise via the transmitting coils 4. For this purpose, a switch 34 (not illustrated in FIG. 1 and FIG. 2) that conducts the output signal from the transmitting coils 4 between the transmission pulses into an evaluation unit 36, where the output signal is decoded and displayed in the form of an image on a display unit 38, is provided. The evaluation unit 36 may be a personal computer, for example.

The magnetic resonance imaging system 24 in FIG. 3 is configured for high field strengths of up to 7 teslas, for which reason local coils are used in order to achieve a field that is as homogeneous as possible. However, the transmitting unit 1 has only a single amplifier 6 designed as an RFPA, to which the signals of the signal generating unit 2 are communicated. The RFPA amplifies the signal and outputs the signal to a power splitter 8, the four output channels of which feed the transmitting coils 4.

In order to be able to further optimize the homogeneity of the magnetic field, in three of the four channels, in each case, phase shifters 10 and damping elements 12 are arranged in a connectable fashion between the power splitter 8 and the respective transmitting coil 4. The phase shifters 10 and damping elements 12 are connectable by PIN diodes. The phase shifters 10 are configured for a discrete phase shift. In an alternative embodiment, the phase shifters 10 have varicaps that enable a continuous phase shift.

The phase shifters 10 and damping elements 12 are driven by a control unit 14. There are a number of possibilities in this case. The phase shifters 10 and damping elements 12 may be set based on operating parameters of the transmitting coils 4 that are stored in coil files in the transmitting coils 4 and are read out by the control unit 14. Alternatively, a test measurement may be effected, during which the disturbances of the homogeneity of the magnetic field are determined, and the phase shifters 10 and damping elements 12 are driven such that the greatest possible homogeneity of the magnetic field is achieved. This may be done automatically or manually using corresponding switches in the user interface.

Alternatively, in the embodiment shown in FIG. 2, a Butler matrix 16 may also be provided, which may be used to excite further modes that, by corresponding selection, may likewise be used for homogenizing the magnetic field. In comparison with the embodiment in FIG. 1, the power splitter 8 is replaced by the Butler matrix 16 in FIG. 2.

The Butler matrix 16 is configured as an 8×8 matrix and thus has eight inputs 18 and eight outputs 20. The single input signal is fed in at one of the inputs 18. The other inputs 18 are terminated via 50-ohm resistors 22. Consequently, different modes are present at the outputs 20. The modes, by corresponding selection of the outputs, may be used for the connection of the transmitting coils 4.

A transmitting unit 1 previously configured for driving an individual whole body transmitting coil may be upgraded for the use of local coils by retrofitting with power splitter 8, phase shifters 10 and damping elements 12.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims can, alternatively, be made to depend in the alternative from any preceding or following claim, whether independent or dependent, and that such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A transmitting unit for a magnetic resonance imaging system, the transmitting unit comprising:
a signal generating unit;
an amplifier connected downstream of the signal generating unit;
a power splitter connected downstream of the amplifier; and
a plurality of electrically decoupled transmitting coils connected downstream of the power splitter,
wherein a corresponding connectable phase shifter is arranged between the power splitter and at least one transmitting coil of the plurality of electrically decoupled transmitting coils.

2. The transmitting unit of claim 1, wherein the respective connectable phase shifter is configured as a discrete phase shifter.

3. The transmitting unit of claim 1, wherein the respective connectable phase shifter is configured as a variable-capacitance diode.

4. The transmitting unit of claim 1, further comprising a connectable damping element arranged between the power splitter and at least one of the transmitting coils.

5. The transmitting unit of claim 4, wherein the respective connectable phase shifter, the respective connectable damping element, or a combination thereof is connectable by a PIN diode.

6. The transmitting unit of claim 4, wherein the transmitting unit is configured to drive the respective connectable phase shifter, the respective connectable damping element, or a combination thereof based on operating parameters of the respectively connected transmitting coil.

7. The transmitting unit of claim 1, wherein the transmitting unit is configured to drive the respective connectable phase shifter, the respective connectable damping element, or a combination thereof based on a test measurement of a magnetic field of the magnetic resonance imaging system.

8. The transmitting unit of claim 1, further comprising a Butler matrix.

9. A method for retrofitting a magnetic resonance imaging system, the method comprising:
upgrading the magnetic resonance imaging system for using a number of electrically decoupled transmitting coils that is greater than a number of amplifiers present by virtue of the transmitting unit;
wherein upgrading comprises arranging a connectable phase shifter between a power splitter and at least one transmitting coil of the number of electrically decoupled transmitting coils of the transmitting unit, the transmitting unit comprising a signal generating unit, an amplifier connected downstream of the signal generating unit, the power splitter connected downstream of the amplifier, and the number of electrically decoupled transmitting coils connected downstream of the power splitter.

10. A magnetic resonance imaging system comprising:
a transmitting unit comprising:
a signal generating unit;
an amplifier connected downstream of the signal generating unit;
a power splitter connected downstream of the amplifier; and
a plurality of electrically decoupled transmitting coils connected downstream of the power splitter,
wherein a corresponding connectable phase shifter is arranged between the power splitter and at least one transmitting coil of the plurality of electrically decoupled transmitting coils.

11. The magnetic resonance imaging system of claim 10, wherein the respective connectable phase shifter is configured as a discrete phase shifter.

12. The magnetic resonance imaging system of claim 10, wherein the respective connectable phase shifter is configured as a variable-capacitance diode.

13. The magnetic resonance imaging system of claim 10, wherein the transmitting unit further comprises a connectable damping element arranged between the power splitter and at least one of the transmitting coils.

14. The magnetic resonance imaging system of claim 13, wherein the respective connectable phase shifter, the respective connectable damping element, or a combination thereof is connectable by a PIN diode.

15. The magnetic resonance imaging system of claim 13, wherein the transmitting unit is configured to drive the respective connectable phase shifter, the respective connectable damping element, or a combination thereof based on operating parameters of the respectively connected transmitting coil.

16. The magnetic resonance imaging system of claim 10, wherein the transmitting unit is configured to drive the respective connectable phase shifter, the respective connectable damping element, or a combination thereof based on a test measurement of a magnetic field of the magnetic resonance imaging system.

17. The magnetic resonance imaging system of claim 10, further comprising a Butler matrix.
